(19) United States
(12) Patent Application Publication
(10) Pub. No.: US 2023/0022359 A1
(43) Pub. Date: Jan. 26, 2023

(54) METHODS, APPARATUS, AND SYSTEMS FOR MAINTAINING FILM MODULUS WITHIN A PREDETERMINED MODULUS RANGE

(71) Applicant: Applied Materials, Inc., Santa Clara, CA (US)

(72) Inventors: Jui-Yuan HSU, San Jose, CA (US); Pramit MANNA, Santa Clara, CA (US); Karthik JANAKIRAMAN, San Jose, CA (US)

(21) Appl. No.: 17/383,101

(22) Filed: Jul. 22, 2021

(51) Int. Cl. H01L 21/26; H01L 21/02; H01J 37/32

(52) U.S. Cl. CPC H01L 21/26; H01L 21/02115; H01J 37/3244; H01J 37/32082; H01J 2237/332

(57) ABSTRACT

Embodiments of the present disclosure generally relate to methods, apparatus, and systems for maintaining film modulus within a predetermined modulus range. In one implementation, a method of processing substrates includes introducing one or more processing gases to a processing volume of a processing chamber, and depositing a film on a substrate supported on a substrate support disposed in the processing volume. The method includes supplying simultaneously a first radiofrequency (RF) power and a second RF power to one or more bias electrodes of the substrate support. The first RF power includes a first RF frequency and the second RF power includes a second RF frequency that is less than the first RF frequency. A modulus of the film is maintained within a predetermined modulus range.

### BACKGROUND

### Field

Embodiments of the present disclosure generally relate to methods, apparatus, and systems for maintaining film modulus within a predetermined modulus range. In one embodiment, which can be combined with other embodiments, a modulus of a film is maintained within a predetermined range while a reduced compressive stress of the film is achieved.

### Description of the Related Art

Reduced compressive stress can enhance device performance for films of semiconductor devices, such as semiconductor devices of integrated circuits. However, conventional attempts to reduce compressive stress inadvertently reduce a modulus of the films, which can cause wiggling, can mechanically deform the films, and can degrade device performance. Wiggling refers to movement of film in a wave pattern. Such drawbacks can become even more pronounced as chip designs continually involve faster circuitry and greater circuit density.

Therefore, there is a need for improved methods, systems, and apparatus that facilitate maintaining film modulus while reducing compressive stress of film to facilitate reduced wiggling, reduced deformation, and enhanced device performance.

### SUMMARY

Embodiments of the present disclosure generally relate to methods, apparatus, and systems for maintaining film modulus within a predetermined modulus range. In one embodiment, which can be combined with other embodiments, a modulus of a film is maintained within a predetermined range while a reduced compressive stress of the film is achieved.

In one implementation, a method of processing substrates includes introducing one or more processing gases to a processing volume of a processing chamber, and depositing an amorphous carbon hardmask film on a substrate supported on a substrate support disposed in the processing volume. The method includes supplying simultaneously a first radiofrequency (RF) power and a second RF power to one or more bias electrodes of the substrate support. The first RF power includes a first RF frequency within a range of 11 MHz to 15 MHz, and the second RF power includes a second RF frequency within a range of 1.8 MHz to 2.2 MHz. A modulus of the amorphous carbon hardmask film is maintained within a predetermined modulus range of 195 GPa or higher.

In one implementation, a non-transitory computer readable medium includes instructions that, when executed, cause a system to introduce one or more processing gases to a processing volume of a processing chamber, and deposit a film on a substrate supported on a substrate support disposed in the processing volume. The instructions, when executed, cause the system to supply simultaneously a first radiofrequency (RF) power and a second RF power to one or more bias electrodes of the substrate support. The first RF power includes a first RF frequency and the second RF power includes a second RF frequency that is less than the first RF frequency. A modulus of the film is maintained within a predetermined modulus range.

In one implementation, a substrate processing system includes a processing chamber having a processing volume, one or more gas sources, a substrate support disposed in the processing volume, and one or more bias electrodes disposed at least partially in the substrate support. The substrate processing system includes a dual-frequency radiofrequency (RF) source electrically coupled to the one or more bias electrodes, and a non-transitory computer readable medium having instructions. The instructions, when executed, cause the substrate processing system to introduce one or more processing gases to the processing volume of the processing chamber, and deposit a film on a substrate supported on the substrate support disposed in the processing volume. The instructions, when executed, cause the substrate processing system to supply simultaneously a first radiofrequency (RF) power and a second RF power to the one or more bias. The first RF power includes a first RF frequency and the second RF power includes a second RF frequency that is less than the first RF frequency. A modulus of the film is maintained within a predetermined modulus range.

### BRIEF DESCRIPTION OF THE DRAWINGS

So that the manner in which the above recited features of the present disclosure can be understood in detail, a more particular description of the disclosure, briefly summarized above, can be had by reference to embodiments, some of which are illustrated in the appended drawings. It is to be noted, however, that the appended drawings illustrate only typical embodiments of this disclosure and are therefore not to be considered limiting of its scope, for the disclosure can admit to other equally effective embodiments.

FIG. 1 is a schematic view of a substrate processing system, according to one implementation.

FIG. 2 is a schematic cross-sectional view of the substrate support shown in FIG. 1, according to one implementation.

FIG. 3 is a schematic view of a substrate processing system, according to one implementation.

FIG. 4 is a schematic flow diagram view of a method of processing substrates, according to one implementation.

FIG. 5 is a schematic view of a graph, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to methods, apparatus, and systems for maintaining film modulus within a predetermined modulus range. In one embodiment, which can be combined with other embodiments, a modulus of a film is maintained within a predetermined range while a reduced compressive stress of the film is achieved. Aspects of the present disclosure may be used with substrate processing systems, such as plasma-enhanced chemical vapor deposition (PECVD) systems.

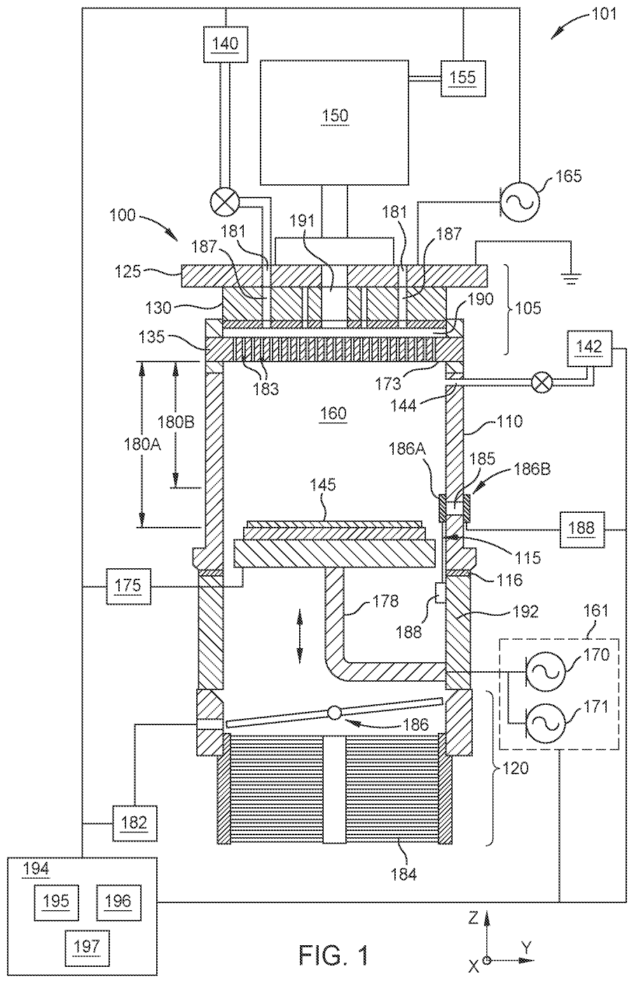

FIG. 1 is a schematic view of a substrate processing system 101, according to one implementation. The substrate processing system 101 includes a processing chamber 100. A side cross-sectional view of the processing chamber 100 is shown in the implementation in FIG. 1.

The processing chamber 100 is configured to conduct a deposition operation on a substrate 145. In one embodiment, which can be combined with other embodiments, the processing chamber 100 is configured to deposit patterning films onto the substrate 145, such as hardmask films, for example, amorphous carbon hardmask films.

The processing chamber 100 includes a lid assembly 105, a spacer 110 disposed on a chamber body 192, a substrate support 115 disposed in a processing volume 160, and a variable pressure system 120. The lid assembly 105 includes a lid plate 125 and a heat exchanger 130. In the embodiment shown, which can be combined with other embodiments described herein, the lid assembly 105 also includes a showerhead 135. The lid assembly 105 can include a concave or dome-shaped gas introduction plate in place of the showerhead 135. The showerhead 135 defines a ceiling 173 of the processing volume 160.

One or more first gas sources 140 (one is shown in FIG. 1) are fluidly coupled to the processing volume 160 through the lid plate 125 and a plenum 190 disposed in the lid assembly 105. The one or more first gas sources 140 introduce processing gases for forming films on the substrate 145 supported on the substrate support 115. The processing gases flow into the plenum 190, through the showerhead 135, and into the processing volume 160. The one or more first gas sources 140 are configured to introduce processing gases such as carbon-containing gases (such as hydrocarbon gases), hydrogen-containing gases, and/or helium. The present disclosure contemplates that other gases may be used. In one example, which can be combined with other examples, the processing gases include one or more of acetylene (C₂H₂) (which can be referred to as ethyne), propene (C₃H₆), methane (CH₄), butene (C₄H₈), 1,3-dimethyladamantane, bicyclo[2.2.1]hepta-2,5-diene (2,5-norbornadiene), adamantine (C₁₀H₁₆), norbornene (C₇H₁₀), any derivatives thereof, and/or any isomers thereof. The processing gases can include one or more dilution gases, one or more carrier gases, etchant gases, and/or one or more purge gases. In one example, which can be combined with other examples, the processing gases include one or more of helium, argon, xenon, neon, nitrogen (N₂), hydrogen (H₂), chlorine (Cl₂), carbon tetrafluoride (CF₄), and/or nitrogen trifluoride (NF₃).

In one embodiment, which can be combined with other embodiments, the one or more first gas sources 140 are configured to introduce acetylene (C₂H₂) and helium (He) into the processing volume 160.

The one or more first gas sources 140 introduce processing gases through one or more channels formed in the lid assembly 105 (such as channels 181, 187 formed in the lid plate 125 and the heat exchanger 130) and into the plenum 190. The one or more channels 181, 187 formed in the lid assembly 105 direct processing gases from the one or more first gas sources 140, through channels 183 formed in the showerhead 135, and into the processing volume 160. In one embodiment, which can be combined with other embodiments, one or more second gas sources 142 (one is shown in FIG. 1) are fluidly coupled to the processing volume 160 through an inlet 144 disposed through a gas ring with nozzles attached to the spacer 110, or through a chamber side wall.

The one or more second gas sources 142 are configured to introduce one or more processing gases such as carbon containing gases, hydrogen containing gases, and/or helium. The present disclosure contemplates that other gases may be used. In one embodiment, which can be combined with other embodiments, the one or more second gas sources 142 are configured to introduce acetylene (C₂H₂) and helium (He) into the processing volume 160. In one embodiment, which can be combined with other embodiments, a total flow rate of processing gases into the processing volume 160—including the flow rates from the one or more first gas sources 140 and the flow rates from the one or more second gas sources 142 (if used)—is about 100 sccm to about 2 slm. The flow of processing gases into the processing volume 160 using the one or more second gas sources 142 is uniformly distributed in the processing volume 160. In one example, which can be combined with other examples, a plurality of inlets 144 may be radially distributed about the spacer 110 or about the chamber sidewall. In such an example, gas flow to each of the inlets 144 may be separately controlled to further facilitate gas uniformity within the processing volume 160.

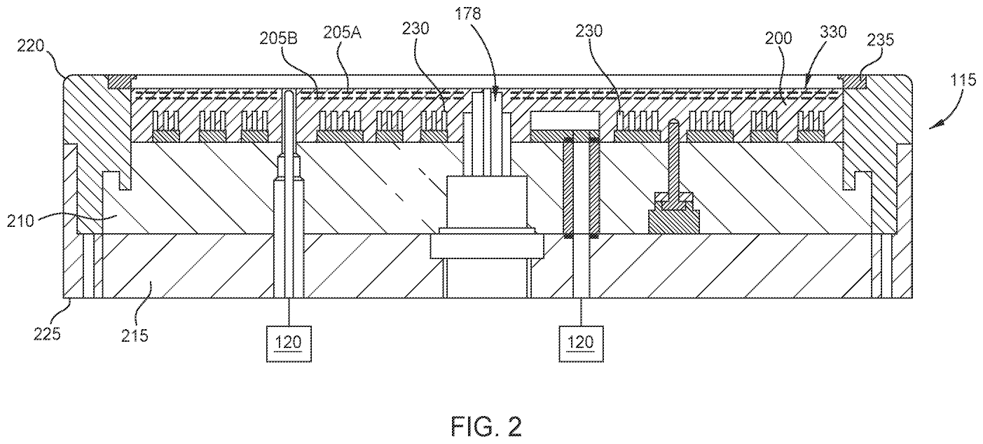

A dual-frequency radiofrequency (RF) power source 161 is electrically coupled to one or more bias electrodes 205B (one is shown in FIG. 2) that are disposed at least partially in the substrate support 115 using a facilities cable 178. The dual-frequency RF power source 161 includes a first RF power source 170 and a second RF power source 171 that are each electrically coupled to the one or more bias electrodes 205B. The first RF power source 170 is configured to supply a first RF power to the one or more bias electrodes 205B, and the second RF power source 171 is configured to supply a second RF power simultaneously with the first RF power. The second RF power is less than the first RF power.

The lid assembly 105 (such as the lid plate 125) is coupled to a third RF power source 165. The third RF power source 165 facilitates maintenance or generation of plasma, such as a plasma generated from a cleaning gas. The third RF power source 165 can facilitate ionizing cleaning gas into a plasma in situ during a cleaning operation. The third RF power source 165 is configured to supply a third RF power to the lid assembly 105, and the third RF power is 40 MHz or greater. The third RF power source 165 is used to clean the upper portion of processing volume 160, such as the showerhead 135. Without being bound by theory, it is believed that the plasma in an upper portion of the processing volume 160 near the showerhead 135 can be of less density and hence the quality of the deposition gas (e.g., ions) in the upper portion can be weak. Using the dual-frequency RF power source 161 and the operational parameters described herein facilitates enhanced deposition, reduced film compressive stress, and maintained film modulus. As an example, the first RF power is used to facilitate generating reactive species and providing ion densities for film deposition, and the second RF power is used to facilitate enhanced ion bombardment for stress reduction.

The first RF power supplied by the first RF power source 170 has a first frequency within a range of 11 MHz to 15 MHz. In one embodiment, which can be combined with other embodiments, the first frequency is 13 MHz or 15 MHz. The second RF power supplied by the second RF power source 171 has a second frequency within a range of 1.8 MHz to 2.2 MHz. In one embodiment, which can be combined with other embodiments, the second frequency is 2 MHz. The present disclosure contemplates that the first RF power source 170 and the second RF power source 171 can be integrated into a mixed frequency RF power source for the dual-frequency RF power source 161 that is configured to simultaneously supply the first RF power and the second RF power. The lid assembly 105 (such as the lid plate 125) is grounded in the implementation shown in FIG. 1. The present disclosure contemplates that the showerhead 135 can be grounded. The present disclosure contemplates that other components surrounding the processing volume 160 (such as the spacer 110) can also be grounded. The present disclosure contemplates that the chamber body 192 can also be grounded.

The dual-frequency RF power source 161 facilitates maintaining modulus for deposited films (deposited on the substrate 145) while reducing compressive stress of the deposited films relative to other films. The dual-frequency RF power source 161 facilitates the maintained modulus while facilitating enhanced implantation of species into deposited film, increased ionization, and increased deposition rates for the film.

In the implementation shown in FIG. 1, the film on the substrate 145 is deposited to a thickness of 3,000 Angstroms or greater, such as 5,000 Angstroms or greater. The present disclosure contemplates that aspects of the present disclosure can be used in implementations where the film is deposited to a thickness of less than 3,000 Angstroms. The film deposited on the substrate 145 is amorphous carbon hardmask film that may subsequently be used as a hardmask during etching operations.

One or more of the dual-frequency RF power source 161 and/or the third RF power source 165 are used to create and/or maintain a plasma in the processing volume 160 while the one or more processing gases are supplied to the processing volume 160 using the one or more first gas sources 140 and/or the one or more second gas sources 142. In one embodiment, which can be combined with other embodiments, the dual-frequency RF power source 161 is used during a deposition operation to deposit film on the substrate 145 and the third RF power source 165 is used during a cleaning operation to remove contaminants or film from interior surfaces of the processing chamber 100.

In the deposition operation, the dual-frequency RF power source 161 simultaneously supplies the first RF power and the second RF power to the one or more bias electrodes 205B of the substrate support 115. The first RF power is within a first power range of 1.5 kW to 1.7 kW, and the second RF power is within a second power range of 400 W to 600 W. In one embodiment, which can be combined with other embodiments, the first RF power is 1.6 kW and the second RF power is 500 W. The first RF power includes a first RF frequency and the second RF power includes a second RF frequency that is less than the first RF frequency. The first RF frequency is within a range of 11 MHz to 15 MHz, such as 13 MHz to 14 MHz, and the second RF frequency is within a range of 1.8 MHz to 2.2 MHz, such as 1.95 MHz to 2.05 MHz. In one embodiment, which can be combined with other embodiments, the first RF frequency is 13 MHz or 14 MHz, and the second RF frequency is 2.0 MHz.

During the deposition operation, the third RF power source 165 can provide a third RF power within a third power range of 100 Watts (W) to about 20 kW. The first RF power, the second RF power, and the third RF power (if the third RF power is used) facilitate ionization of the one or more processing gases, and the ions of the one or more processing gases bombard onto the substrate 145 to deposit the films on the substrate 145. In one embodiment, which can be combined with other embodiments, the one or more processing gases include acetylene (C₂H₂) and helium (He). In one example, which can be combined with other examples, acetylene (C₂H₂) is provided to the processing volume 160 at a flow rate of within a range of 10 sccm to 1,000 sccm, such as 100 sccm to 200 sccm, and helium (He) is provided at a flow rate within a range of 50 sccm to 5,000 sccm, such as 100 sccm to 200 sccm. In one embodiment, which can be combined with other embodiments, acetylene (C₂H₂) is provided to the processing volume 160 at a flow rate of within a range of 140 sccm to 160 sccm, such as 145 sccm to 155 sccm, and helium (He) is provided at a flow rate within a range of 140 sccm to 160 sccm, such as 145 sccm to 155 sccm. In one embodiment, which can be combined with other embodiments, acetylene (C₂H₂) is provided to the processing volume 160 at a flow rate of 150 sccm, and helium (He) is provided at a flow rate of 150 sccm.

The substrate support 115 is coupled to an actuator 175 (e.g., a lift actuator) that provides movement thereof along the Z direction. The substrate support 115 is coupled to the facilities cable 178 that is flexible which allows vertical movement of the substrate support 115 while maintaining couplings with the dual-frequency power source 161 as well as other power and fluid couplings. The spacer 110 is disposed on the chamber body 192. A height of the spacer 110 allows movement of the substrate support 115 vertically within the processing volume 160. The height of the spacer 110 is about 0.5 inches to about 20 inches. In one embodiment, which can be combined with other embodiments, the substrate support 115 is movable from a first distance 180A to a second distance 180B relative to the ceiling 173 defined by the showerhead 135. In one embodiment, which can be combined with other embodiments, the second distance 1806 is about ⅔ of the first distance 180A. A difference between the first distance 180A and the second distance 180B is about 5 inches to about 6 inches. From the position shown in FIG. 1, the substrate support 115 is movable by about 5 inches to about 6 inches relative to a lower surface of the showerhead 135. In one embodiment, which can be combined with other embodiments, the substrate support 115 is fixed at one of the first distance 180A and the second distance 180B.

During the deposition operation, the processing volume 160 and/or the substrate 145 is maintained at a deposition temperature and a deposition pressure. The deposition temperature is within a range of −50 degrees Celsius to 600 degrees Celsius. In one embodiment, which can be combined with other embodiments, the deposition temperature is within a range of 8 degrees Celsius to 12 degrees Celsius, such as 10 degrees Celsius. The deposition pressure is sub-atmospheric. The deposition pressure is within a range of 0.1 mTorr to 500 mTorr. The deposition pressure is within a range of 3 mTorr to 5 mTorr, such as 4 mTorr. During the deposition operation the substrate support 115 is disposed at the second distance 180B, and the second distance is within a range of 3.5 inches to 4.5 inches, such as 4.0 inches.

The variable pressure system 120 includes a first pump 182 and a second pump 184. The first pump 182 is a roughing pump that may be used during a cleaning operation and/or substrate transfer operation. A roughing pump is generally configured for moving higher volumetric flow rates and/or operating a relatively higher (though still sub-atmospheric) pressure. In one example, which can be combined with other examples, the first pump 182 maintains a pressure within the processing chamber less than 50 mtorr during a cleaning operation. In one example, which can be combined with other examples, the first pump 182 maintains a pressure within the processing chamber of about 0.5 mTorr to about 10 Torr. Utilization of a roughing pump during cleaning operations facilitates relatively higher pressures and/or volumetric flow of cleaning gas (as compared to a deposition operation). The relatively higher pressure and/or volumetric flow during the cleaning operation facilitates improved cleaning of interior chamber surfaces.

The second pump 184 may be a turbo pump and/or a cryogenic pump.

The second pump 184 is utilized during a deposition operation. The second pump 184 is generally configured to operate a relatively lower volumetric flow rate and/or pressure. The second pump 184 is configured to maintain the processing volume 160 of the processing chamber at a pressure of less than about 50 mTorr, such as about 0.5 mtorr to about 10 Torr. The reduced pressure of the processing volume 160 maintained during deposition facilitates deposition of a film having reduced compressive stress and/or increased sp² to spa conversion, when depositing carbon-based hardmasks. Thus, processing chamber 100 is configured to utilize both relatively lower pressure to facilitate improved deposition and relatively higher pressure to facilitate improved cleaning.

A valve 186 is used to control the conductance path to one or both of the first pump 182 and the second pump 184. The valve 186 also provides symmetrical pumping from the processing volume 160.

The processing chamber 100 also includes a substrate transfer port 185. The substrate transfer port 185 is selectively sealed by an interior door 186A and an exterior door 186B. Each of the doors 186A and 186B are coupled to actuators 188 (e.g., a door actuator). The doors 186A and 1866 facilitate vacuum sealing of the processing volume 160. The doors 186A and 186B also provide symmetrical RF application and/or plasma symmetry within the processing volume 160. In one example, at least the interior door 186A is formed of a material that facilitates conductance of RF power, such as stainless steel, aluminum, or alloys thereof. Seals 116, such as O-rings, disposed at the interface of the spacer 110 and the chamber body 192 may further seal the processing volume 160.

The lid assembly 105 is coupled to an optional remote plasma source 150. The remote plasma source 150 is fluidly coupled to a cleaning gas source 155 for providing cleaning gases to the processing volume 160 formed inside the spacer 110 between the lid assembly 105 and the substrate 145. In one example, which can be combined with other examples, cleaning gases are provided through a central conduit 191 formed axially through the lid assembly 105. In one example, which can be combined with other examples, cleaning gases are provided through the same channels of the lid assembly 105 that direct the processing gases to the processing volume 160 from the one or more first gas sources 140. Example cleaning gases include one or more of: oxygen-containing gases such as oxygen and/or ozone, fluorine containing gases such as NF₃, and/or hydrogen containing gases such as dihydrogen. In one embodiment, which can be combined with other embodiments, the remote plasma source 150 is used to introduce radicals into the processing volume 160, such as hydrogen radicals and/or oxygen radicals.

The channels 181, 187, a central conduit 191, and the channels 183 can be oriented vertically (e.g., parallel to the Z-axis) and/or can be oriented at an angle (such as an oblique angle) relative to the X-Y plane.

The remote plasma source 150 can be used in place of or in addition to the third RF power source 165 during the cleaning operation. The present disclosure contemplates that the remote plasma source 150 can be omitted, and the cleaning gases can be ionized into a plasma in situ using the third RF power source 165.

The substrate processing system 101 includes a controller 194 to control the operations of the substrate processing system 101. The controller 194 is coupled to the one or more first gas sources 140, the one or more second gas sources 142, one or more clean gas sources 155, the actuator 175, the first pump 182, the dual-frequency RF power source 161, the third RF power source 165, and/or the actuators 188 to control the operations thereof. The controller 194 includes a central processing unit (CPU) 195 (a processor), a memory 196 containing instructions, and support circuits 197 for the CPU 195. The controller 194 controls the substrate processing system 101 directly, or via other computers and/or controllers (not shown) coupled to the processing chamber 100. The controller 194 is of any form of a general-purpose computer processor that is used in an industrial setting for controlling various chambers and equipment, and sub-processors thereon or therein.

The memory 196 (a non-transitory computer readable medium) is one or more of a readily available memory such as random access memory (RAM), read only memory (ROM), floppy disk, hard disk, flash drive, or any other form of digital storage, local or remote. The support circuits 197 are coupled to the CPU 195 for supporting the CPU 195 (a processor). The support circuits 197 include cache, power supplies, clock circuits, input/output circuitry and subsystems, and the like.

Substrate processing parameters and operations are stored in the memory 196 as a software routine that is executed or invoked to turn the controller 194 into a specific purpose controller to control the operations of the substrate processing system 101. The parameters stored in the memory 196 can include, for example, the first RF frequency, the second RF frequency, the first power range, the second power range, the frequency ratio range, the second distance 1806, the deposition temperature, and/or the deposition pressure. The controller 194 is configured to conduct any of the methods and operations described herein. The instructions stored in the memory 196, when executed by the processor 195, cause one or more of operations 402-410 of method 400 to be conducted.

The instructions in the memory 196 of the controller 194 can include one or more machine learning algorithms and/or one or more artificial intelligence algorithms that can be executed in addition to the operations described herein. As an example, a machine learning algorithm or artificial intelligence algorithm executed by the controller 194 can optimize and alter the parameters stored in the memory 196 based on measurements taken during or after operations, such as the deposition operation and/or the cleaning operation. The optimized parameters can include, for example, the first RF frequency, the second RF frequency, the first power range, the second power range, the frequency ratio range, the second distance 180B, the deposition temperature, and/or the deposition pressure. As an example, a machine learning algorithm or artificial intelligence algorithm stored in the memory 196 and executed by the processor 195 can use measurements of film modulus and film compressive stress to optimize the first RF frequency and the second RF frequency of the dual-frequency RF power source 161.

The spacer 110 includes a height that is about 0.5 inches to about 20 inches, such as about 0.5 inches to about 3 inches, such as about 10 inches to about 20 inches, such as about 14 inches to about 16 inches. The spacer 110 provides part of a volume of the processing volume 160. The height of the processing volume 160 provides many benefits. One benefit includes a reduction in film stress which decreases stress induced bow in the substrate 145 being processed therein. The height of the processing volume 160 affects plasma density distribution from top to bottom of the processing volume 160. Methods provided herein facilitate maintaining plasma density in the lower portion of the processing volume 160 suitable for film deposition on substrate 145 disposed on the substrate support 115 by using the dual-frequency RF power source 161.

FIG. 2 is a schematic cross-sectional view of the substrate support 115 shown in FIG. 1, according to one implementation. The substrate support 115 includes an electrostatic chuck 230. The electrostatic chuck 230 includes a puck 200. The puck 200 includes one or more electrodes embedded therein, such as a first electrode 205A and a second electrode 205B. The first electrode 205A is a chucking electrode electrically coupled to a direct current (DC) power source, and the second electrode 205B is an RF biasing electrode electrically coupled to the dual-frequency RF power source 161. The frequency provided to the second electrode 205B may be pulsed. The puck 200 is formed from a dielectric material, such as a ceramic material, for example aluminum nitride (AlN).

The puck is supported by a dielectric plate 210 and a base plate 215. The dielectric plate 210 may be formed from an electrically insulative material, such as quartz, or a thermoplastic material, such as high performance plastics sold under the tradename REXOLITE®. The base plate 215 may be made from a metallic material, such as aluminum. During operation, the base plate 215 is coupled to ground or is electrically floating while the puck 200 is RF hot. At least the puck 200 and the dielectric plate 210 are surrounded by an insulator ring 220. The insulator ring 220 may be made of a dielectric material such as quartz, silicon, or a ceramic material. The base plate 215 and a portion of the insulator ring 220 is surrounded by a ground ring 225 made of aluminum. The insulator ring 220 reduced or eliminates arcing between the puck 200 and the base plate 215 during operation. An end of the facilities cable 178 is shown in openings formed in the puck 200, the dielectric plate 210 and the base plate 215. Power for the electrodes 205A, 205B of the puck 200, as well as fluids from a gas supply to the substrate support 115, is provided by the facilities cable 178.

An edge ring 235 is disposed adjacent to an inner circumference of the insulator ring 220. The edge ring 235 may include a dielectric material, such as quartz, silicon, cross-linked polystyrene and divinylbenzene (e.g., REXOLITE®), PEEK, Al₂O₃, AlN, among others. Utilizing an edge ring 235 that includes such a dielectric material facilitates modulating the plasma coupling, modulating the plasma properties, such as the voltage on the substrate support 115 (V_{dc}), without having to change the plasma power, thus facilitating improved properties for hardmask films deposited on substrates (such as the substrate 145). By modulating the RF coupling to the substrate 145 through the material of the edge ring 235, the modulus of the film can be decoupled from the stress of the film.

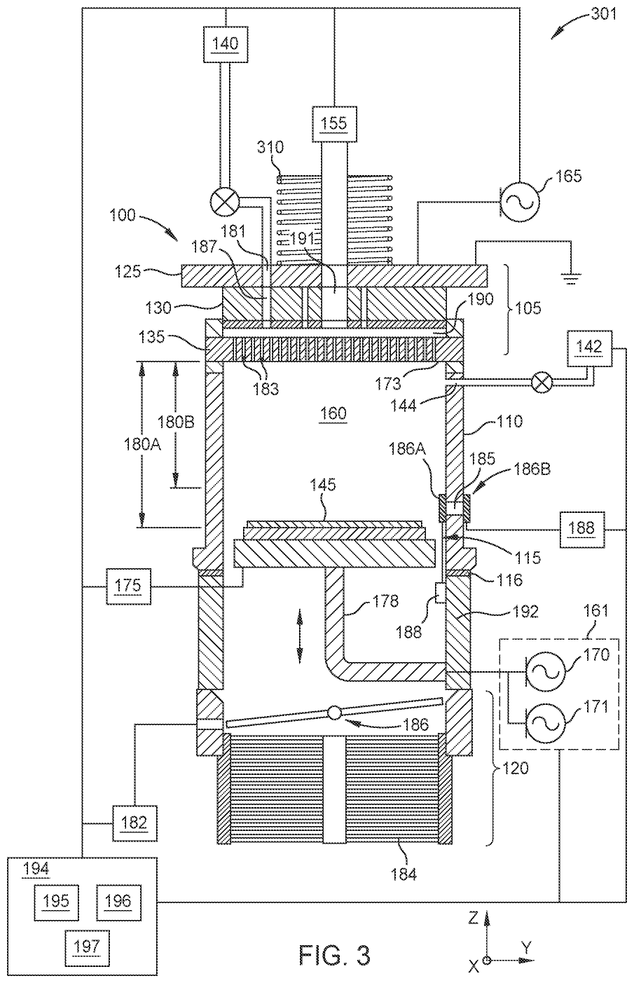

FIG. 3 is a schematic view of a substrate processing system 301, according to one implementation. The substrate processing system 301 is similar to the substrate processing system 101 shown in FIG. 1, and includes one or more of the aspects, features, components, and/or properties thereof. In the implementation shown in FIG. 3, the remote plasma source 150 is omitted, and a flat coil 310 is used (with or without the third RF power source 165) during the cleaning operation to excite a cleaning plasma in the processing volume 160 while the one or more cleaning gas sources 155 introduce cleaning gases to the processing volume 160. The flat coil 310 is used to generate cleaning plasma in-situ during the cleaning operation.

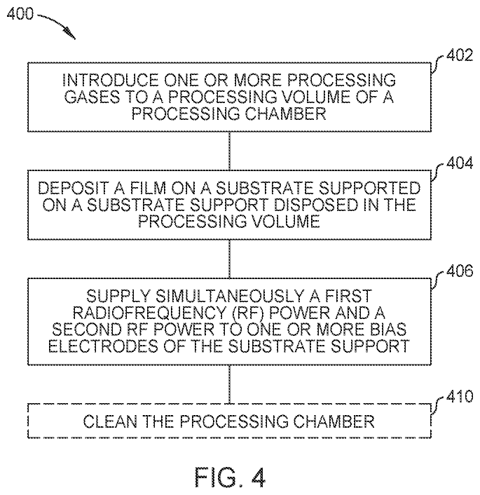

FIG. 4 is a schematic flow diagram view of a method 400 of processing substrates, according to one implementation. Operation 402 includes introducing one or more processing gases to a processing volume of a processing chamber. The one or more processing gases include acetylene (C₂H₂) and helium (He).

Operation 404 includes depositing a film on a substrate supported on a substrate support disposed in the processing volume. The depositing the film can include ionizing the one or more processing gases using a plasma to generate ions of the one or more processing gases, and bombarding the substrate with the ions. The film is an amorphous carbon film. The film is deposited to a thickness of 3,000 Angstroms or greater. The film can be deposited on one or more layers, and the one or more layers include oxide and/or nitride.

Operation 406 includes supplying simultaneously a first radiofrequency (RF) power and a second RF power to one or more bias electrodes of the substrate support. The first RF power includes a first RF frequency and the second RF power includes a second RF frequency that is less than the first RF frequency. The first RF frequency is within a range of 11 MHz to 15 MHz, such as 13 MHz to 14 MHz, and the second RF frequency is within a range of 1.8 MHz to 2.2 MHz, such as 1.95 MHz to 2.05 MHz. In one embodiment, which can be combined with other embodiments, the first RF frequency is 13 MHz, 13.56 MHz, or 14 MHz, and the second RF frequency is 2.0 MHz. The present disclosure contemplates that the first RF frequency can be higher, such as 26 MHz, 40 MHz, 60 MHz, or 100 MHz. The present disclosure contemplates that the second RF frequency can be lower, such as 350 KHz.

Each of the first RF power and the second RF power is within a range of 500 W to 10 kW. In one embodiment, which can be combined with other embodiments, the first RF power is within a first power range of 1.5 kW to 1.7 kW, and the second RF power is within a second power range of 400 W to 600 W. In one embodiment, which can be combined with other embodiments, the first RF power is 1.6 kW and the second RF power is 500 W. The first RF power facilitates generating plasma having reactive species and sufficient ion densities in the processing volume, and the second RF power facilitates attracting ions in the processing volume toward the substrate being processed for ion bombardment. The values of the first RF power and the second RF power can be negative or positive depending on the charge of the ions of the processing gases. If the ions are negatively charged, then the values of the first RF power and the second RF power are positive. If the ions are positively charged, then the values of the first RF power and the second RF power are negative.

The second RF frequency is within a frequency ratio range of the second RF frequency relative to the first RF frequency, and the frequency ratio range is 0.1 to 0.2. As an example, in an embodiment where the first RF frequency is 13 MHz, the second RF frequency is within a range of 1.3 MHz to 2.6 MHz due to the frequency ratio range. An overall bias frequency (determined by adding together the first RF frequency and the second RF frequency together) is 18 MHz or less. In one embodiment, which can be combined with other embodiments, the first RF power includes a first voltage and the second RF power includes a second voltage that is lesser than the first voltage. Each of the first voltage and the second voltage is a direct current (DC) voltage. The present disclosure contemplates that the second voltage can be equal to or greater than the first voltage. In one embodiment, which can be combined with other embodiments, operation 402, operation 404, and operation 406 are conducted simultaneously.

A modulus of the film is maintained within a predetermined modulus range during the depositing of operation 404 and the supplying simultaneously the first RF power and the second RF power of operation 406. The modulus is a Young's modulus. The predetermined modulus range is 195 GPa or higher. A compressive stress of the film is maintained within a range of 500 MPa to 1500 MPa. The values of the compressive stress may be considered as negative values because the stress is compressive, but the values for the compressive stress are described as positive values herein.

The modulus of the film is maintained at a modulus ratio. The modulus ratio is a ratio of the modulus relative to a compressive stress of the film. The modulus ratio is a value determined by dividing the modulus by the compressive stress. As an example, in an embodiment where the compressive stress is 687 MPa and the modulus is 199 GPa, the modulus ratio is about 289. The modulus ratio is maintained to be 200 or greater. In one embodiment, which can be combined with other embodiments, the modulus ratio is within a modulus ratio range of 185 to 300. The deposited film can be a diamond-like carbon film.

The supplying the first RF power and the second RF power of operation 406 is conducted simultaneously with the deposition of operation 404. During the depositing, the one or more processing gases are ionized by a first RF field generated using the first RF power to generate one or more plasmas having one or more reactive species. The one or more plasmas can be one or more capacitive-coupled plasmas. The one or more plasmas can include one or more electrons, one or more ions, and/or one or more radicals. The film is deposited on the substrate using energetic bombardment of ions from the one or more plasmas and chemical reaction(s) between the one or more plasmas and surface material(s) of the substrate. The first RF power is used to facilitate generating the one or more reactive species of the one or more plasmas and providing sufficient ion densities for the one or more plasmas. The second RF power facilitates enhanced ion bombardment for reduction in stresses of the deposited film.

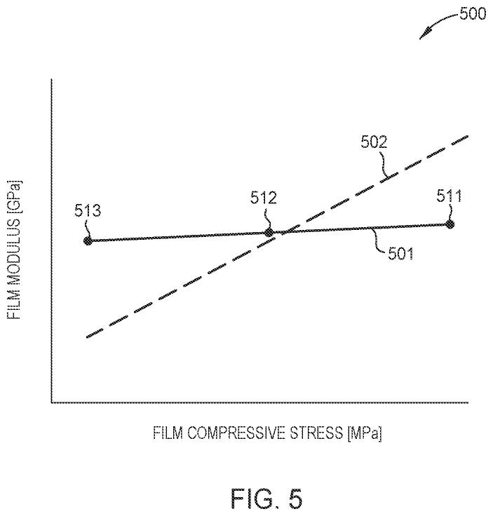

Optional operation 410 includes cleaning the processing chamber. The cleaning includes removing contaminants and/or film from interior surfaces of the processing chamber. The cleaning includes supplying a third RF power to a lid assembly of the processing chamber. The third RF power includes a third frequency that is 40 MHz or more. FIG. 5 is a schematic view of a graph 500, according to one implementation. The graph 500 includes a first profile 501, which is plotted using parameters disclosed herein during deposition testing operations. A second profile 502 is plotted using other parameters. According to the second profile 502, the modulus of deposited films is reduced when the compressive stress of the films is reduced. According to the first profile 501, the modulus of deposited films is maintained (relative to the second profile 502) when compressive stress of the deposited films is reduced. Parameters described herein, such as the first RF frequency, the second RF frequency, the first power range, the second power range, the frequency ratio range, the second distance 180B, the deposition temperature, and the deposition pressure were used to generate the first profile 501.

As an example, the first RF power of 1.6 kW, the first RF frequency of 13 MHZ, the second RF frequency of 2 MHz, the second distance 180B of 4.0 inches, the deposition temperature of 10 degrees Celsius, and the deposition pressure of 4 mTorr, were used to create three points 511-513 of the first profile 501. A second RF power of 0 W was used for a first point 511, which resulted in a compressive stress of 1056 MPa and a modulus of 202.5 GPa. A second RF power of 200 W was used for a second point 512, which resulted in a compressive stress of 848 MPa and a modulus of 201.6 GPa. A second RF power of 500 W was used for a third point 513, which resulted in a compressive stress of 687 MPa and a modulus of 197.3 GPa. Hence, the compressive stress can be reduced along the first profile 501 while maintaining the modulus relative to the reduced modulus of the second profile 502. For example, at the same compressive stress of 687 MPa, the second profile 502 results in the lower modulus value of approximately 188 GPa.

As shown in the first profile 501 of FIG. 5, subject matter described herein facilitates unexpected results as it was previously thought that reducing the compressive stress of film would result in substantial reductions in modulus of the film (as shown in the second profile 502). The parameters disclosed herein (such as the first RF frequency, the second RF frequency, the first power range, the second power range, the frequency ratio range, the second distance 180B, the deposition temperature, and the deposition pressure) facilitate the unexpected results.

Benefits of the present disclosure include reducing compressive stress of deposited films while maintaining modulus of the deposited films, reduced film wiggling, reduced deformation of films and substrates, enhanced etching performance for hardmasks, and enhanced device performance.

As an example, it is believed that the present disclosure (such as by using the first RF power and the second RF power) facilitates a 35% reduction in film stress while maintaining the modulus within a predetermined range (such as a range of 195 GPa or higher). As another example, it is believed that the second voltage being lesser than the first voltage with the second RF frequency being lesser than the first RF frequency facilitates enhanced film deposition and ion bombardment to reduced compressive stress of the film while maintaining a modulus (e.g., a Young's modulus) of the deposited film.

It is contemplated that one or more aspects disclosed herein may be combined. As an example, one or more aspects, features, components, and/or properties of the substrate processing system 101, the substrate processing system 301, the method 400, and/or the graph 500 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

1. A method of processing substrates, comprising:
introducing one or more processing gases to a processing volume of a processing chamber;
depositing an amorphous carbon hardmask film on a substrate supported on a substrate support disposed in the processing volume, the depositing the amorphous carbon hardmask film comprising:
bombarding the substrate with ions of one or more plasmas, and chemically reacting the substrate with the one or more plasmas;
supplying simultaneously a first radiofrequency (RF) power and a second RF power to one or more bias electrodes of the substrate support, the first RF power comprising a first RF frequency within a range of 11 MHz to 15 MHz, and the second RF power comprising a second RF frequency within a range of 1.8 MHz to 2.2 MHz, wherein a modulus of the amorphous carbon hardmask film is maintained within a predetermined modulus range of 195 GPa or higher.

2. The method of claim 1, wherein the first RF power is within a first power range of 1.5 kW to 1.7 kW, and the second RF power is within a second power range of 400 W to 600 W.

3. The method of claim 2, wherein:
the one or more processing gases comprise acetylene (C₂H₂) and helium (He);
each of the acetylene (C₂H₂) and the helium (He) is introduced to the processing volume at a flow rate within a range of 145 sccm to 155 sccm;
the first RF power comprises a first voltage and the second RF power comprises a second voltage that is lesser than the first voltage;
the amorphous carbon hardmask film is deposited at a deposition temperature within a range of 8 degrees Celsius to 12 degrees Celsius and a deposition pressure within a range of 3 mTorr to 5 mTorr; and
the substrate support is positioned at a distance relative to a ceiling of the processing volume during the depositing the amorphous carbon hardmask film and the supplying simultaneously the first RF power and the second RF power, and the distance is within a range of 3.5 inches to 4.5 inches.

4. The method of claim 3, wherein the flow rate of each of the acetylene (C₂H₂) and the helium (He) is 150 sccm.

5. The method of claim 1, wherein the amorphous carbon hardmask film is deposited to a thickness of 3,000 Angstroms or greater.

6. The method of claim 1, wherein the second RF frequency is within a frequency ratio range of the second RF frequency divided by the first RF frequency, and the frequency ratio range is 0.1 to 0.2.

7. The method of claim 1, wherein the modulus is maintained at a modulus ratio, the modulus ratio is a ratio of the modulus divided by a compressive stress of the amorphous carbon hardmask film, and the modulus ratio is 200 or greater.

8. The method of claim 1, wherein a compressive stress of the amorphous carbon hardmask film is within a range of 500 MPa to 1500 MPa.

9. A non-transitory computer readable medium comprising instructions that, when executed, cause a system to:
introduce one or more processing gases to a processing volume of a processing chamber;
deposit a film on a substrate supported on a substrate support disposed in the processing volume;
supply simultaneously a first radiofrequency (RF) power and a second RF power to one or more bias electrodes of the substrate support, the first RF power comprising a first RF frequency and the second RF power comprising a second RF frequency that is less than the first RF frequency, a modulus of the film is maintained within a predetermined modulus range.

10. The non-transitory computer readable medium of claim 9, wherein a compressive stress of the film is within a range of 500 MPa to 1500 MPa.

11. The non-transitory computer readable medium of claim 9, wherein the first RF frequency is within a range of 11 MHz to 15 MHz, and the second RF frequency is within a range of 1.8 MHz to 2.2 MHz.

12. The non-transitory computer readable medium of claim 11, wherein the first RF power is within a first power range of 1.5 kW to 1.7 kW, and the second RF power is within a second power range of 400 W to 600 W.

13. The non-transitory computer readable medium of claim 12, wherein the film is deposited to a thickness of 3,000 Angstroms or greater.

14. The non-transitory computer readable medium of claim 13, wherein the film is an amorphous carbon film.

15. The non-transitory computer readable medium of claim 9, wherein the second RF frequency is within a frequency ratio range of the second RF frequency divided by the first RF frequency, and the frequency ratio range is 0.1 to 0.2.

16. The non-transitory computer readable medium of claim 9, wherein the modulus is maintained at a modulus ratio, the modulus ratio is a ratio of the modulus divided by a compressive stress of the film, and the modulus ratio is 200 or greater.

17. A substrate processing system, comprising:
a processing chamber comprising a processing volume;
one or more gas sources;
a substrate support disposed in the processing volume;
one or more bias electrodes disposed at least partially in the substrate support;
a dual-frequency radiofrequency (RF) source electrically coupled to the one or more bias electrodes;
a non-transitory computer readable medium comprising instructions that, when executed, cause the substrate processing system to:
introduce one or more processing gases to the processing volume of the processing chamber,
deposit a film on a substrate supported on the substrate support disposed in the processing volume,
supply simultaneously a first radiofrequency (RF) power and a second RF power to the one or more bias electrodes, the first RF power comprising a first RF frequency and the second RF power comprising a second RF frequency that is less than the first RF frequency, wherein a modulus of the film is maintained within a predetermined modulus range.

18. The substrate processing system of claim 17, wherein the predetermined modulus range is 195 GPa or higher.

19. The substrate processing system of claim 18, wherein the first RF frequency is within a range of 11 MHz to 15 MHz.

20. The substrate processing system of claim 19, wherein the second RF frequency is within a range of 1.8 MHz to 2.2 MHz.
